(19) United States
(12) Patent Application Publication
(10) Pub. No.: US 2025/0351430 A1
(43) Pub. Date: Nov. 13, 2025

(54) MANUFACTURING METHOD OF A SEMICONDUCTOR WAFER AND A SEMICONDUCTOR WAFER

(71) Applicant: Renesas Electronics Corporation, Tokyo (JP)

(72) Inventors: Takeshi KISHIDA, Tokyo (JP); Hiroki SHINKAWATA, Tokyo (JP)

(21) Appl. No.: 19/069,368

(22) Filed: Mar. 4, 2025

(30) Foreign Application Priority Data
May 9, 2024 (JP) 2024-076306

(51) Int. Cl. H10D 30/66; H01L 23/00; H10D 30/01; H10D 62/10; H10D 64/00

(52) U.S. Cl. CPC H10D 30/668; H01L 23/562; H10D 30/0297; H10D 62/127; H10D 64/117

(57) ABSTRACT

A semiconductor device capable of controlling the warpage of a semiconductor wafer is provided. A semiconductor wafer is provided in which a first semiconductor chip with a first trench arranged in a first direction and a second semiconductor chip with a second trench arranged in a second direction different from the first direction are alternately arranged laterally. In the semiconductor wafer, it is possible that a first semiconductor chip with a first trench arranged in a first direction and a second semiconductor chip with a second trench arranged in a second direction different from the first direction are alternately arranged longitudinally.

### CROSS-REFERENCE TO RELATED APPLICATIONS

The disclosure of Japanese Patent Application No. 2024-076306 filed on May 9, 2024, including the specification, drawings and abstract is incorporated herein by reference in its entirety.

### BACKGROUND

This disclosure relates to a semiconductor wafer and a method for manufacturing a semiconductor wafer.

There is a disclosed techniques listed below.
[Patent Document 1] Japanese Unexamined Patent Application Publication No. 2024-1723

Patent Document 1 discloses a power MOSFET (Metal Oxide Semiconductor Field Effect Transistor) with a field plate electrode and a gate electrode formed in a trench.

### SUMMARY

However, since the trenches are arranged in parallel in one direction on the semiconductor chip, there was a problem that the semiconductor wafer with multiple semiconductor chips formed would warp. Therefore, the purpose of this disclosure is to provide a semiconductor device with controlled warpage by forming semiconductor chips with trenches extending in a first direction and semiconductor chips with trenches extending in a second direction.

Other objects and novel features will become apparent from the description of this specification and the accompanying drawings.

According to one embodiment, the semiconductor wafer has a first semiconductor chip with a first trench arranged in a first direction and a second semiconductor chip with a second trench arranged in a second direction different from the first direction, alternately arranged.

According to the embodiment, a semiconductor device that can control the warpage of the semiconductor wafer can be provided.

### BRIEF DESCRIPTION OF THE DRAWINGS

FIG. 1 is a plan view showing a related semiconductor device.

FIG. 2 is an enlarged plan view showing a main part of a related semiconductor device.

FIG. 3 is an enlarged plan view showing a main part of a related semiconductor device.

FIG. 4 is a cross-sectional view showing a related semiconductor device.

FIG. 5 is a cross-sectional view showing a related semiconductor device.

FIG. 6 is a layout of trenches of a related semiconductor device.

FIG. 7 is a diagram showing the wafer warpage of a related semiconductor device.

FIG. 8 is a layout of trenches of a semiconductor wafer according to the first embodiment.

FIG. 9 is a layout of trenches of a semiconductor wafer according to the second embodiment.

FIG. 10 is a layout of trenches of a semiconductor wafer according to the third embodiment.

### DETAILED DESCRIPTION

### Embodiment

An embodiment of the present invention will be described with reference to the accompanying drawings. However, the invention according to the claims is not limited to the following embodiments. Also, not all configurations described in the embodiments are essential as means for solving the problems. For clarity of explanation, the following description and drawings are appropriately omitted and simplified. In the drawings, the same reference numerals are used for the same elements, and redundant descriptions are omitted as necessary.

Also, the X, Y, and Z directions described in this application intersect and are orthogonal to each other. In this application, the Z direction is described as the vertical, height, or thickness direction of a structure. Also, expressions such as “plan view” or “plan view” used in this application mean a plane formed by the X and Y directions, viewed from the Z direction.

### (Description of the Configuration and Problems of Related Semiconductor Devices)

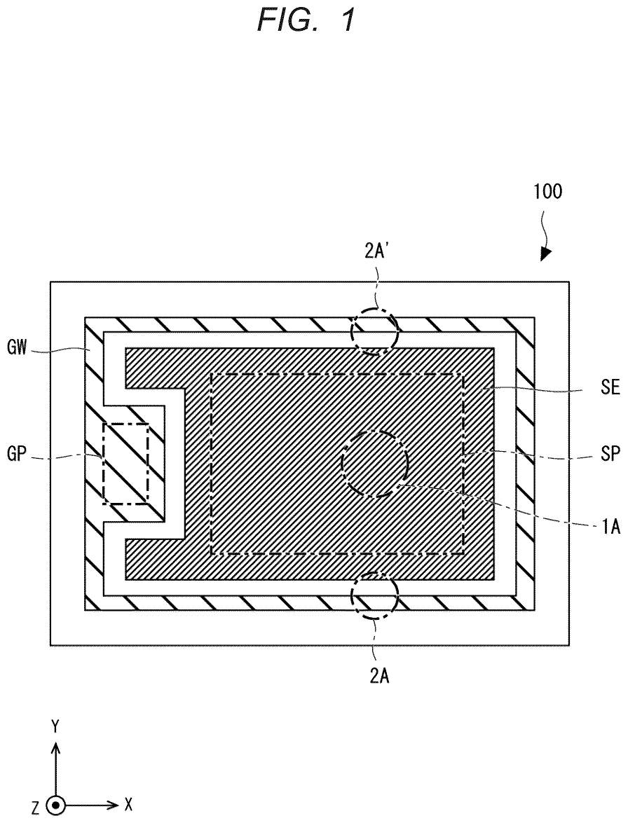

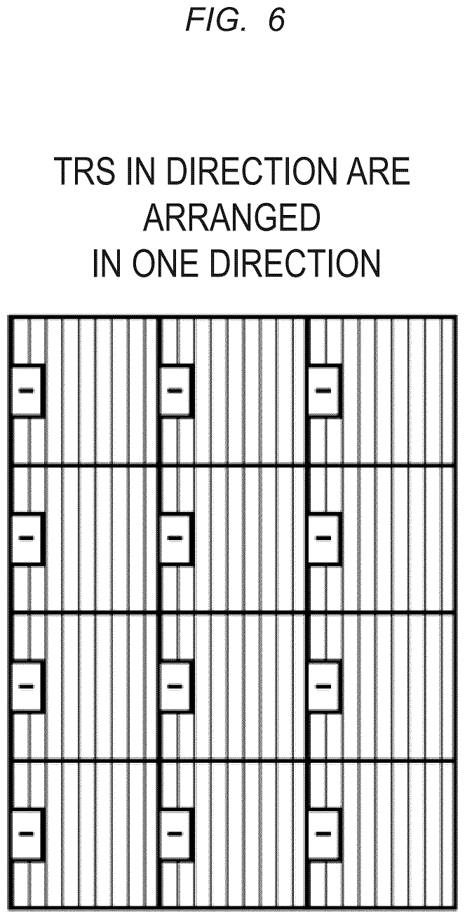

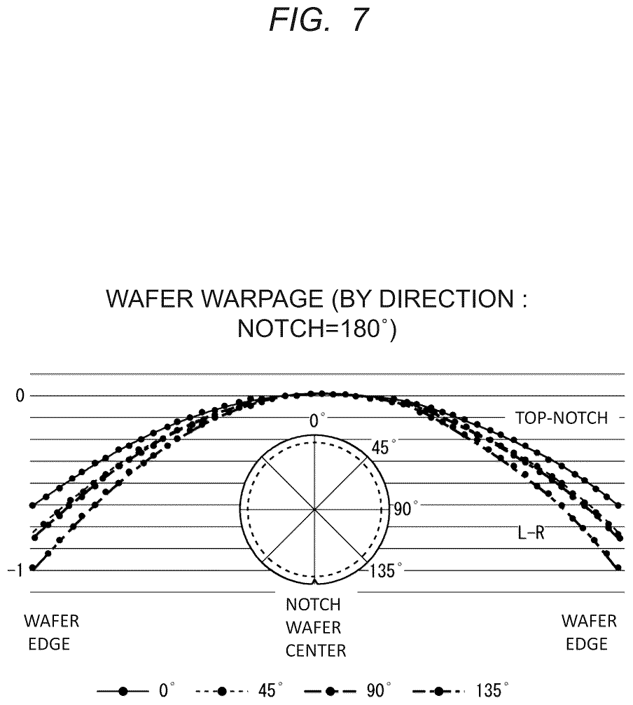

The related semiconductor device 100 will be described below with reference to FIGS. 1 to 5. Also, the problems of the related semiconductor device will be described with reference to FIGS. 6 and 7. The semiconductor device 100 includes a MOSFET with a trench gate structure as a semiconductor element. In particular, the related MOSFET has a split gate structure with a gate electrode GE and a field plate electrode FP.

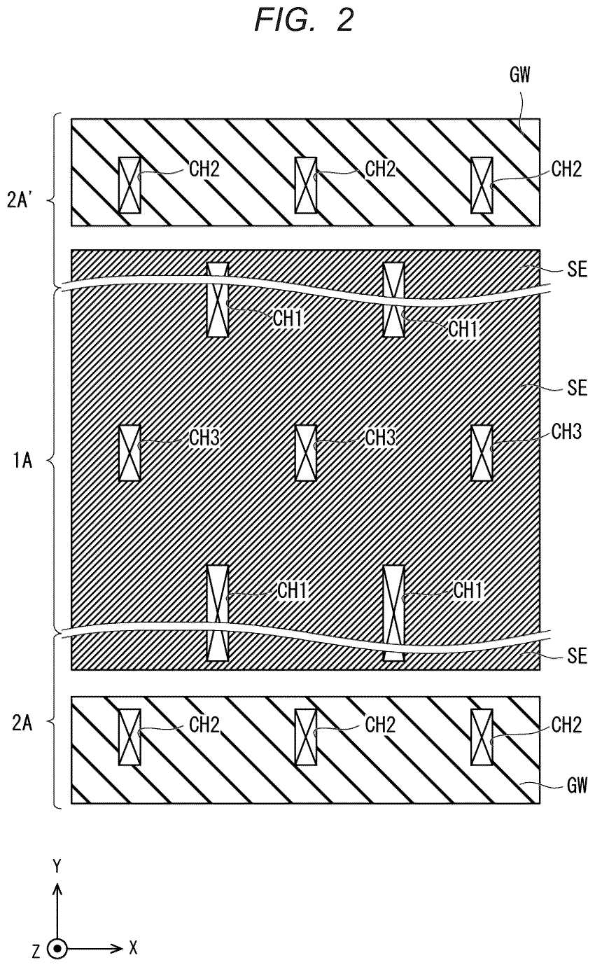

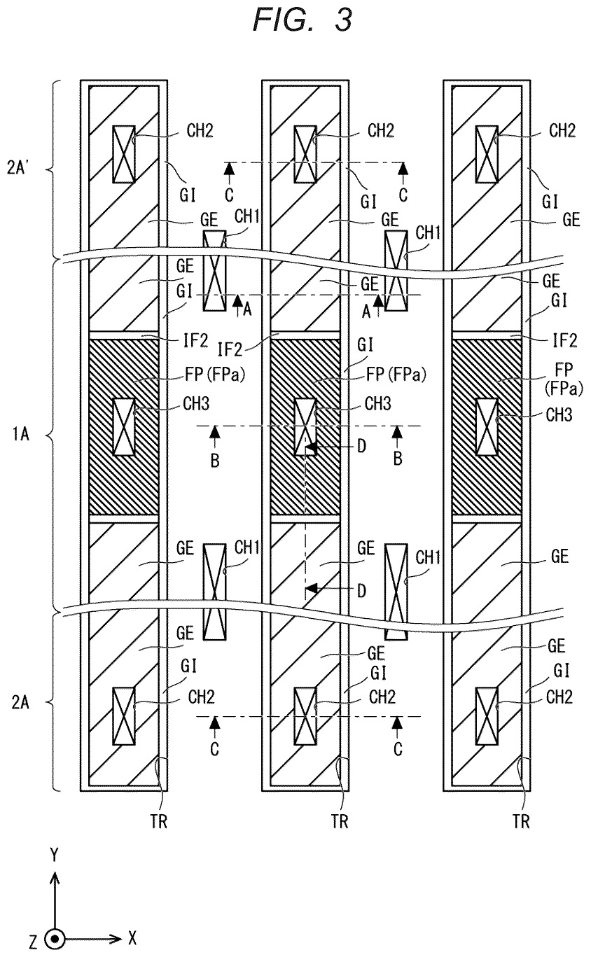

FIG. 1 is a plan view of a semiconductor chip, which is semiconductor device 100. FIG. 1 mainly shows a wiring pattern formed above the semiconductor substrate SUB. FIG. 2 is an enlarged plan view of a main part of FIG. 1. FIG. 3 shows the structure below FIG. 2, showing the structure of the trench gate formed in the semiconductor substrate SUB.

As shown in FIG. 1, most of the semiconductor device 100 is covered with a source electrode (fixed potential supply wiring) SE. The gate wiring GW is provided along the outer periphery of semiconductor device 100, surrounding the source electrode SE in plain view. Although not shown here, the source electrode SE and the gate wiring GW are covered with a protective film such as a polyimide film. Openings are provided in part of the protective film, and the source electrode SE and gate wiring GW exposed in the openings become the source pad SP and gate pad GP. External connection members such as wire bonding or clips (copper plates) are connected to the source pad SP and the gate pad GP, so that the semiconductor device 100 is electrically connected to other semiconductor chips or wiring boards.

The semiconductor device 100 also includes region 1A and regions 2A, 2A′ surrounding the region 1A in plain view. Region 1A is a cell region where main semiconductor elements such as multiple MOSFETs are formed. Regions 2A, 2A′ are peripheral regions used for e.g., connecting the gate wiring GW to the gate electrode GE.

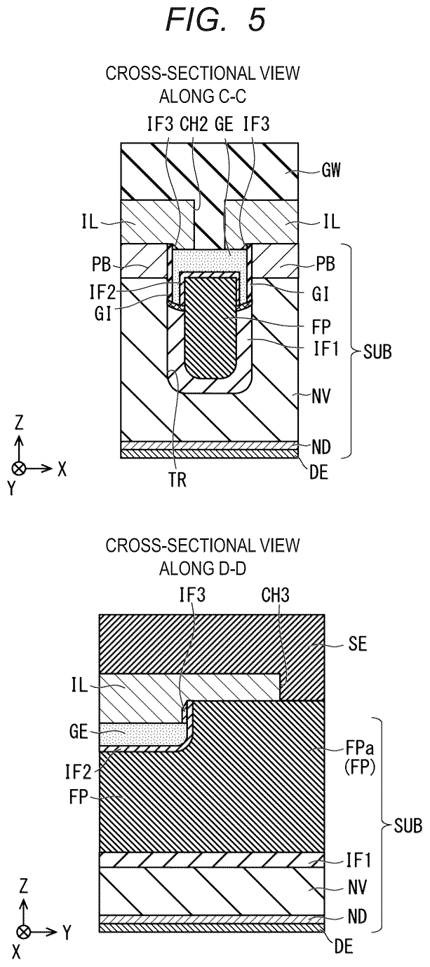

The positional relationship of holes CH1 to CH3 shown in FIG. 3 matches the positional relationship of holes CH1 to CH3 shown in FIG. 2. The structure of region 2A′ is an inversion of the structure of region 2A on the drawing. Therefore, the cross-sectional structure of region 2A′ is similar to that of region 2A, as shown in the C-C section of FIG. 5.

As shown in FIG. 3, multiple trenches TR extend in the Y direction and are adjacent to each other in the X direction. The width of each trench TR in the X direction is, for example, 1.5 micrometers or more and 1.8 micrometers or less.

Inside the trench TR, a field plate (fixed potential electrode) FP is formed at the bottom of the trench TR, and a gate electrode GE is formed at the top of the trench TR. Therefore, in FIG. 3, the gate electrode GE is exposed. The field plate electrode FP and the gate electrode GE extend in the Y direction along the trench TR.

A part of the field plate electrode FP forms a contact portion FPa. The field plate electrode FP forming the contact portion FPa is formed not only at the bottom of the trench TR but also at the top of the trench TR inside the trench TR of region 1A. Therefore, in FIG. 3, the contact portion FPa is exposed.

The gate electrode GE is divided into region 2A side and the region 2A′ side by the contact portion FPa.

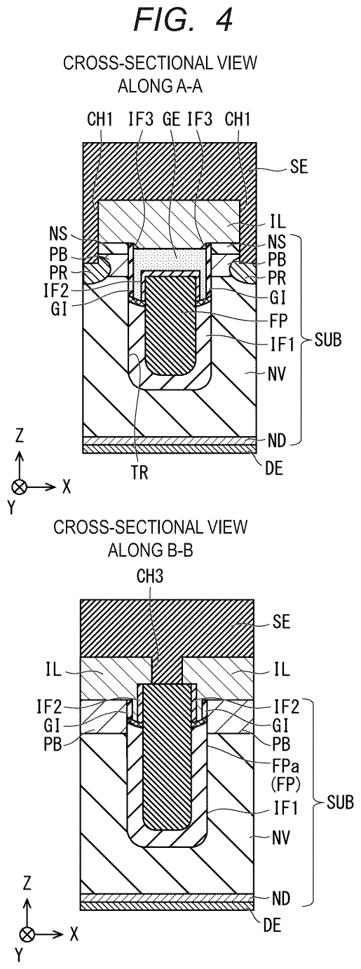

The cross-sectional structure of the semiconductor device 100 will be described below with reference to FIGS. 4 and 5. FIG. 4 is a cross-sectional view along the A-A and B-B lines shown in FIG. 3. FIG. 5 is a cross-sectional view along the C-C and D-D lines shown in FIG. 3.

First, the basic structure of the MOSFET will be described using the A-A section of FIG. 4. The semiconductor device 100 includes a semiconductor substrate SUB having an upper surface and a lower surface. The semiconductor substrate SUB has a low-concentration n-type drift region NV. Here, the n-type semiconductor substrate SUB itself constitutes the drift region NV. The drift region NV may be an n-type semiconductor layer grown on an n-type silicon substrate by introducing phosphorus (P) through epitaxial growth. In this application, such a laminate consisting of an n-type silicon substrate and an n-type semiconductor layer is also described as the semiconductor substrate SUB.

Multiple trenches TRI reaching a predetermined depth from the upper surface of the semiconductor substrate SUB are formed in the semiconductor substrate SUB. The depth of each trench is, for example, 5 micrometers or more and 7 micrometers or less. Inside the trench TR, a field plate electrode FP is formed at the bottom of the trench TR via an insulating film IF1. The position of the upper surface of the insulating film IF1 is lower than the position of the upper surface of the field plate electrode FP. An insulating film IF2 is formed on the upper surface and side surfaces of the field plate electrode FP exposed from the insulating film IF1. A gate insulating film GI is formed on the semiconductor substrate SUB inside the trench TR.

Inside the trench TR, a gate electrode GE is formed at the top of the trench TR. The gate electrode GE is electrically insulated from the field plate electrode FP by the insulating film IF2 and is electrically insulated from the semiconductor substrate SUB by the gate insulating film GI. The gate electrode GE is also formed between the field plate electrode FP exposed from the insulating film IF1 and the semiconductor substrate SUB via the gate insulating film GI and the insulating film IF2.

The upper surface of the gate electrode GE is slightly recessed compared to the upper surface of the semiconductor substrate SUB. On a portion of the upper surface of the gate electrode GE, an insulating film IF3 is formed so as to contact the gate insulating film GI.

The gate electrode GE and the field plate electrode FP are made of, for example, a polycrystalline silicon film into which n-type impurities are introduced. The insulating films IF1, IF2, IF3, and the gate insulating film GI are made of, for example, a silicon oxide film.

The thickness of the insulating film IF1 is greater than that of each of the insulating films IF2, IF3, and the gate insulating film GI. The thickness of the insulating film IF1 is, for example, 400 nm or more and 600 nm or less. The thickness of each of the insulating film IF2 and the gate insulating film is, for example, 50 nm or more and 80 nm or less. The thickness of the insulating film IF3 is, for example, 30 nm or more and 80 nm or less.

On the upper surface side of the semiconductor substrate SUB, a p-type body region PB is formed in the semiconductor substrate SUB to be shallower than the trench TR. An n-type source region NS is formed in the body region PB. The source region NS has a higher impurity concentration than the drift region NV.

On the lower surface side of the semiconductor substrate SUB, an n-type drain region ND is formed in the semiconductor substrate SUB. The drain region ND has a higher impurity concentration than the drift region NV. A drain electrode DE is formed below the lower surface of the semiconductor substrate SUB. The drain electrode DE is made of, for example, a single-layer metal film such as an aluminum film, titanium film, nickel film, gold film, or silver film, or a laminated film obtained by appropriately laminating these metal films.

On the upper surface of the semiconductor substrate SUB, an interlayer insulating film IL is formed to cover the trench TR. The interlayer insulating film IL is made of, for example, a silicon oxide film. The thickness of the interlayer insulating film IL is, for example, 700 nm or more and 900 nm or less. The interlayer insulating film IL may be a laminated film of a thin silicon oxide film and a thick silicon oxide film containing phosphorus (PSG: Phosphorus Silicate Glass film).

In the interlayer insulating film IL, in the source region NS and the body region PB, a hole CH1 is formed. At the bottom of the hole CH1, a high concentration region PR is formed in the body region PB. The high concentration region PR has a higher impurity concentration than the body region PB.

On the interlayer insulating film IL, a source electrode SE is formed. The source electrode SE is embedded inside the hole CH1. The source electrode SE is electrically connected to the source region NS, the body region PB, and the high concentration region PR, supplying them with a source potential (fixed potential).

As shown in the C-C cross-section of FIGS. 3 and 5, the gate electrode GE includes a first end on the region 2A side and a second end on the region 2A′ side in the Y direction. A hole CH2 is formed inside the interlayer insulating film IL. The hole CH2 on the region 2A side is formed to overlap the first end of the gate electrode GE in plan view, and the hole CH2 on the region 2A′ side is formed to overlap the second end of the gate electrode GE in plan view.

Here, the “first end of the gate electrode GE” described in this specification refers to the portion of the gate electrode GE where the hole CH2 of region 2A is provided and which is adjacent to the body region PB where the source region NS is not formed, as shown in the C-C cross-section of FIG. 5. Similarly, the “second end of the gate electrode GE” described in this specification refers to the portion of the gate electrode GE where the hole CH2 of region 2A′ is provided and which is adjacent to the body region PB where the source region NS is not formed, as shown in the C-C cross-section of FIG. 5.

On the interlayer insulating film IL, a gate wiring GW is formed. The gate wiring GW is embedded inside the hole CH2. The gate wiring GW is electrically connected to the gate electrode GE, supplying the gate electrode GE with a gate potential.

As shown in the B-B cross-section of FIGS. 3 and 4 and the D-D cross-section of FIG. 5, a part of the field plate electrode FP forms the contact portion FPa of the field plate electrode FP. The contact portion FPa is formed not only at the lower part of the trench TR but also at the upper part of the trench TR, inside the trench TR located between the gate electrode GE on the region 2A side (first end side) and the gate electrode GE on the region 2A′ side (second end side).

Moreover, the position of the upper surface of the insulating film IF1 in contact with the field plate electrode FP other than the contact portion FPa is lower than the position of the upper surface of the insulating film IF1 in contact with the contact portion FPa. That is, the position of the upper surface of the insulating film IF1 in the A-A cross-section is located at a depth of, for example, 700 nm or more and 900 nm or less from the upper surface of the semiconductor substrate SUB. The position of the upper surface of the insulating film IF1 in the B-B cross-section is located at a depth of, for example, 600 nm or more and 800 nm or less from the upper surface of the semiconductor substrate SUB.

Furthermore, the position of the upper surface of the contact portion FPa is higher than the position of the upper surface of the semiconductor substrate SUB, and is located at a height of, for example, 200 nm or more and 400 nm or less from the upper surface of the semiconductor substrate SUB.

The connecting portion GEa is formed on both side surfaces of the contact portion FPa via the insulating film IF2 in the X direction. The connecting portion GEa extends in the Y direction and connects the gate electrode GE on the region 2A side (first end side) and the gate electrode GE on the region 2A′ side (second end side). The gate electrode GE and the connecting portion GEa are made of an integrated n-type polycrystalline silicon film. Therefore, the gate potential is also supplied to the connecting portion GEa from the gate wiring GW. The connecting portion GEa is covered with the insulating film IF3.

A hole CH3 is formed in the interlayer insulating film IL. The hole CH3 is formed to overlap the contact portion FPa in plain view. The source electrode SE is embedded inside the hole CH3. The source electrode SE is electrically connected to the field plate electrode FP, supplying the field plate electrode FP with a source potential.

Moreover, the source electrode SE and the gate wiring GW are composed of, for example, a barrier metal film and a conductive film formed on the barrier metal film. The barrier metal film is, for example, a titanium nitride film, and the conductive film is, for example, an aluminum film.

The source electrode SE and the gate wiring GW may be composed of a plug layer embedded in the holes CH1 to CH3 and a wiring layer formed on the interlayer insulating film IL. In that case, the wiring layer is composed of barrier metal film and conductive film. The plug layer is composed of a barrier metal film such as titanium nitride film and a conductive film such as tungsten film.

Such a semiconductor device is called a split-gate type MOSFET.

FIG. 6 shows the layout of trenches in the related semiconductor device. As shown in FIG. 6, the layout of trenches in the related semiconductor device is arranged in parallel in one direction in the semiconductor wafer.

FIG. 7 is a diagram showing the wafer warpage of the related semiconductor device. The wafer in FIG. 7 is a wafer in which trenches are arranged linearly with respect to the notch or the orientation flat. As shown in FIG. 7, the amount of warpage of the wafer is smallest at 0 degrees, which is the direction straight to the notch. Next, the warpage amount is large at 45 degrees or 135 degrees with respect to the notch. The warpage amount is largest at 90 degrees with respect to the notch.

Thus, when the trenches are arranged parallel to the notch, the warpage in the left-right direction with respect to the notch becomes large. Therefore, it may affect wafer transport and have a negative impact on productivity.

### (Description of the Semiconductor Wafer According to the First Embodiment)

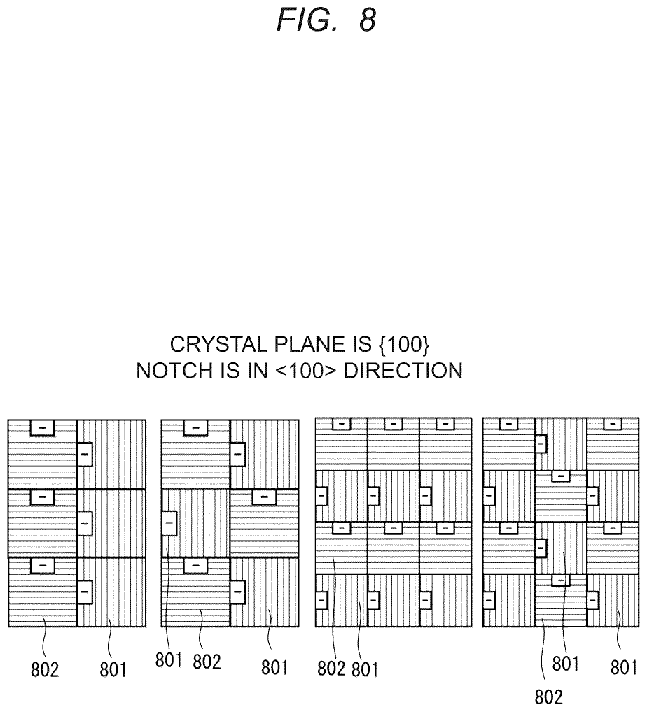

FIG. 8 shows the layout of trenches in the semiconductor wafer according to the first embodiment. The semiconductor wafer according to the first embodiment will be described with reference to FIG. 8.

FIG. 8 is a plan view of a semiconductor wafer in which the crystal plane of the surface is {100}, and the notch or the orientation flat is in the <100> direction. The lower side of FIG. 8 is the position of the notch or the orientation flat. As shown in the left diagram of FIG. 8, a first semiconductor chip 801 with a first trench arranged in a first direction and a second semiconductor chip 802 with a second trench arranged in a second direction different from the first direction are alternately arranged side by side. In this case, the first semiconductor chip 801 and the second semiconductor chip 802 are alternately arranged side by side in a row with the notch or the orientation flat facing down.

As shown in the third diagram from the left in FIG. 8, a first semiconductor chip 801 with a first trench arranged in a first direction and a second semiconductor chip 802 with a second trench arranged in a second direction different from the first direction may be alternately arranged longitudinally. In this case, the first semiconductor chip 801 and the second semiconductor chip 802 are alternately arranged longitudinally in a row with the notch or orientation flat facing down. As shown in the second and fourth diagrams from the left in FIG. 8, a first semiconductor chip 801 with a first trench arranged in a first direction and a second semiconductor chip 802 with a second trench arranged in a second direction different from the first direction may be alternately arranged longitudinally and laterally. In this case, the first semiconductor chip 801 and the second semiconductor chip 802 are arranged in a checkered grid pattern.

By arranging in this manner, a semiconductor device capable of controlling the warpage of the semiconductor wafer can be provided.

The first direction and the second direction may intersect at a right angle. For example, the first direction of the first trench of the first semiconductor chip 801 is at 0 degrees when the notch or the orientation flat is viewed from the front. The second direction of the second trench of the second semiconductor chip 802 is at 90 degrees when the notch or the orientation flat is viewed from the front.

Here, the electrical properties of the semiconductor device are considered. In the semiconductor device according to the first embodiment, the reason why the trench is formed at 0 degrees or 90 degrees with respect to the notch is to improve the electrical characteristics by using a silicon wafer with a {100} surface and a notch in the <100> direction, making the channel of the trench MOSFET as a {100} surface.

The first semiconductor chip 801 and the second semiconductor chip 802 preferably form a square, respectively. When the first semiconductor chip 801 and the second semiconductor chip 802 form squares, they can be arranged on the semiconductor wafer without gaps. Additionally, the warpage of the semiconductor wafer can be accurately controlled.

The first trench and the second trench are preferably created in the same process. For this reason, the mask pattern is created so that the first trench and the second trench are fabricated simultaneously. This manufacturing method allows the production of semiconductor wafers without increasing the number of manufacturing steps.

### (Description of the Semiconductor Wafer According to the Second Embodiment)

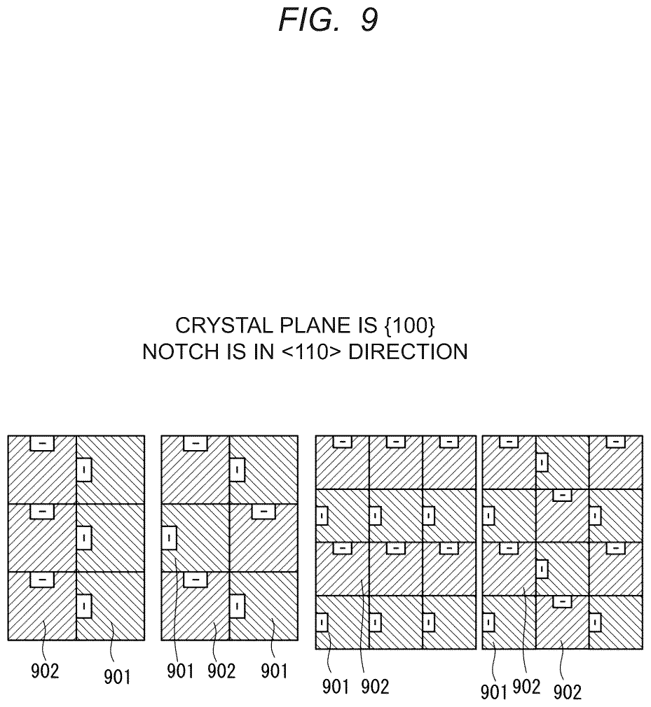

FIG. 9 shows the layout of the trenches of the semiconductor wafer according to the second embodiment. The semiconductor wafer according to the second embodiment will be described with reference to FIG. 9.

FIG. 9 is a plan view of a semiconductor wafer where the crystal plane of the surface is {100}, and the notch or the orientation flat is in the <110> direction. The lower side of FIG. 9 indicates the position of the notch or the orientation flat. As shown in the left diagram of FIG. 9, the first semiconductor chip 901 with the first trench arranged in the first direction and the second semiconductor chip 902 with the second trench arranged in the second direction different from the first direction are alternately arranged laterally. In this case, the first semiconductor chip 901 and the second semiconductor chip 902 are alternately arranged laterally in a row with the notch or the orientation flat facing down.

As shown in the third diagram from the left in FIG. 9, the first semiconductor chip 901 with the first trench arranged in the first direction and the second semiconductor chip 902 with the second trench arranged in the second direction different from the first direction may be alternately arranged longitudinally. In this case, the first semiconductor chip 901 and the second semiconductor chip 902 are alternately arranged longitudinally in a row with the notch or the orientation flat facing down.

As shown in the second and fourth diagrams from the left in FIG. 9, the first semiconductor chip 901 with the first trench arranged in the first direction and the second semiconductor chip 902 with the second trench arranged in the second direction different from the first direction may be alternately arranged both longitudinally and laterally. In this case, the first semiconductor chip 901 and the second semiconductor chip 902 are arranged in a checkered grid pattern.

By arranging them in this manner, a semiconductor device capable of controlling the warpage of the semiconductor wafer can be provided.

The first direction and the second direction may intersect at a right angle. For example, the first direction of the first trench of the first semiconductor chip 901 is at 45 degrees when the notch or the orientation flat is viewed from the front. The second direction of the second trench of the second semiconductor chip 902 is at 135 degrees when the notch or the orientation flat is viewed from the front.

Here, the electrical properties of the semiconductor device are considered. In the semiconductor device according to the second embodiment, the reason why the trench is formed at 45 degrees or 135 degrees with respect to the notch is to improve the electrical characteristics by using a silicon wafer with a {100} surface and a notch in the <110> direction, making the channel of the trench MOSFET as a {100} surface.

The first semiconductor chip 901 and the second semiconductor chip 902 preferably form a square, respectively.

When the first semiconductor chip 901 and the second semiconductor chip 902 form squares, they can be arranged on the semiconductor wafer without gaps. Additionally, the warpage of the semiconductor wafer can be accurately controlled.

Similar to the first embodiment, the first trench and the second trench are preferably created in the same process. For this reason, the mask pattern is created so that the first trench and the second trench are fabricated simultaneously. This manufacturing method allows the production f semiconductor wafers without increasing the number of manufacturing steps.

### (Description of the Semiconductor Wafer According to the Third Embodiment)

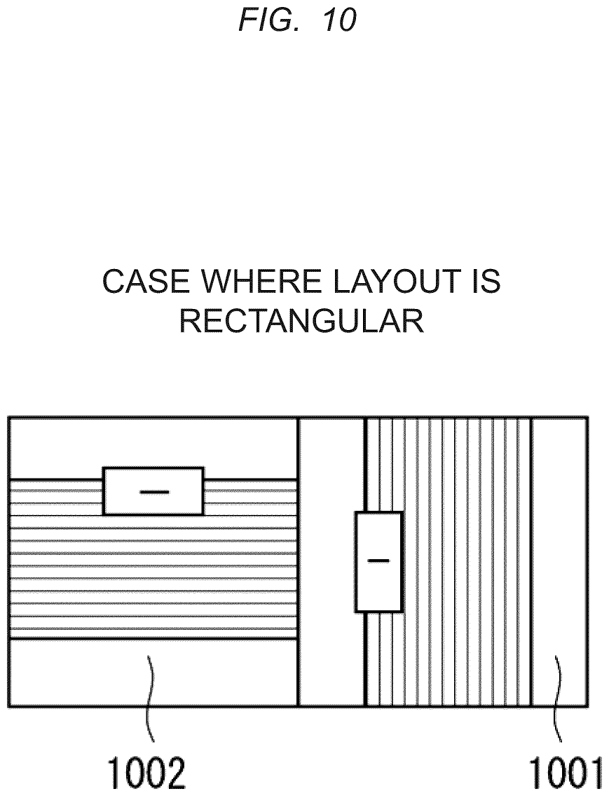

FIG. 10 shows the layout of the trenches of the semiconductor wafer according to the third embodiment. The semiconductor wafer according to the third embodiment will be described with reference to FIG. 10.

As shown in FIG. 10, consider the case where the arrangement of the MOSFET forms a rectangle with respect to the semiconductor chip. Even in such cases, the first semiconductor chip 1001 and the second semiconductor chip 1002 form a square, respectively. By doing so, the first semiconductor chip 1001 and the second semiconductor chip 1002 can be arranged on the semiconductor wafer without gaps. Additionally, the warpage of the semiconductor wafer can be accurately controlled.

For example, in the semiconductor device according to the above embodiments, the conductivity type (p-type or n-type) of the semiconductor substrate, semiconductor layer, diffusion layer (diffusion region), etc., may be inverted. Therefore, in the case where one of the conductivity types of the n-type or the p-type is the first conductivity type and the other conductivity type is the second conductivity type, the first conductivity type can be the p-type and the second conductivity type can be the n-type, or on the contrary, the first conductivity type can be the n-type and the second conductivity type can be the p-type.

Although the invention made by the inventor has been specifically described based on the embodiment, the present invention is not limited to the embodiment already described, and it is needless to say that various modifications can be made without departing from the gist thereof.

1. A semiconductor wafer in which a first semiconductor chip with a first trench arranged in a first direction and a second semiconductor chip with a second trench arranged in a second direction different from the first direction are alternately arranged laterally and/or longitudinally.

2.-3. (canceled)

4. The semiconductor wafer according to claim 1, wherein the first direction intersects at a right angle with the second direction.

5. The semiconductor wafer according to claim 1, wherein the first semiconductor chip forms a square, and the second semiconductor chip forms a square.

6. The semiconductor wafer according to claim 1, wherein a crystal plane of a surface of the semiconductor wafer is a {100} plane,
wherein a notch or an orientation flat of the semiconductor wafer is in a <100> direction, and
wherein, when the notch or the orientation flat of the semiconductor wafer is viewed from a front, the first direction is at 0 degrees and the second direction is at 90 degrees.

7. The semiconductor wafer according to claim 1,
wherein a crystal plane of a surface of the semiconductor wafer is a {100} plane;
wherein a notch or an orientation flat of the semiconductor wafer is in a <110> direction; and
wherein, when the notch or the orientation flat of the semiconductor wafer is viewed from a front, the first direction is at 45 degrees and the second direction is at 135 degrees.

8. A method of manufacturing a semiconductor wafer in which a first semiconductor chip with a first trench arranged in a first direction and a second semiconductor chip with a second trench arranged in a second direction different from the first direction are alternately arranged laterally and/or longitudinally, by forming the first trench and the second trench in a same process.

9.-10. (canceled)

11. The method of manufacturing a semiconductor wafer according to claim 6, wherein the first direction intersects at a right angle with the second direction.

12. The method of manufacturing a semiconductor wafer according to claim 6, wherein the first semiconductor chip forms a square, and the second semiconductor chip forms a square.

13. The method of manufacturing a semiconductor wafer according to claim 6,
wherein a crystal plane of a surface of the semiconductor wafer is a {100} plane;
wherein a notch or an orientation flat of the semiconductor wafer is in a <100> direction; and
wherein, when the notch or the orientation flat of the semiconductor wafer is viewed from a front, the first direction is at 0 degrees and the second direction is at 90 degrees.

14. The method of manufacturing a semiconductor wafer according to claim 6,
wherein a crystal plane of a surface of the semiconductor wafer is a {100} plane;
wherein a notch or an orientation flat of the semiconductor wafer is in a <110> direction; and
wherein, when the notch or the orientation flat of the semiconductor wafer is viewed from a front, the first direction is at 45 degrees and the second direction is at 135 degrees.
